(19) United States
(12) Patent Application Publication
(10) Pub. No.: US 2014/0167806 A1
(43) Pub. Date: Jun. 19, 2014

(54) SEMICONDUCTOR DEVICE TESTING APPARATUS

(71) Applicant: Electronics and Telecommunications Research Institute, Daejeon (KR)

(72) Inventors: Chul Won JU, Daejeon (KR); Hyung Sup Yoon, Daejeon (KR); Jong-Won Lim, Daejeon (KR); Sang-Heung Lee, Daejeon (KR); Seong-il Kim, Daejeon (KR); Dong Min Kang, Daejeon (KR); Eun Soo Nam, Daejeon (KR); Jae Kyoung Mun, Daejeon (KR)

(73) Assignee: Electronics and Telecommunications Research Institute, Daejeon (KR)

(21) Appl. No.: 14/020,931

(22) Filed: Sep. 9, 2013

(30) Foreign Application Priority Data
Dec. 14, 2012 (KR) 10-2012-0146827

(51) Int. Cl. G01R 1/04

(52) U.S. Cl. CPC G01R 1/0466
USPC 324/756.02

(57) ABSTRACT

Provided is a semiconductor device testing apparatus including a first socket configured to load a package, on which a semiconductor device to be tested may be mounted, and a second socket coupled to the first socket. The first socket may include an upper part including a hole configured to accommodate the package and a terminal pad provided at both side edges of the hole to hold input and output terminals of the package, and a lower part including a heating room, in which a heater and a temperature sensing part may be provided, the heater being configured to heat the semiconductor device and the temperature sensing part being configured to measure temperature of the semiconductor device. The second socket may include a probe card with a pattern that may be configured to receive test signals from an external power source.

### CROSS-REFERENCE TO RELATED APPLICATIONS

This U.S. non-provisional patent application claims priority under 35 U.S.C. §119 to Korean Patent Application No. 10-2012-0146827, filed on Dec. 14, 2012, in the Korean Intellectual Property Office, the entire contents of which are hereby incorporated by reference.

### BACKGROUND OF THE INVENTION

Example embodiments of the inventive concept relate to an apparatus for testing a semiconductor device, and in particular, to an apparatus configured to test electric characteristics and reliability of a semiconductor device.

Silicon semiconductor devices occupy about 90-95% of the total semiconductor market, and silicon semiconductor devices of various types are being manufactured. Each of the silicon semiconductor devices is provided in a form of the standardized package structure. Accordingly, an apparatus for testing silicon semiconductor devices is provided in a form of the standardized structure. For example, the standardized testing apparatus is used to measure electric characteristics, at room temperature, and reliability of silicon semiconductor devices.

An AlGaN/GaN high electron mobility transistor (HEMT) is a power semiconductor device that is widely used for high power applications. Since the power semiconductor device has a power of several watts to several hundreds of watts, it should be configured to have a good heat dissipation property. Further, low parasitic inductance is needed for RF HEMT.

Compound semiconductor power devices are manufactured in a small-quantity batch-production manner, and thus, they are not provided in a form of the standardized package structure, unlike the silicon semiconductor devices. Therefore, there is no commercialized testing apparatus with a standardized structure. As a result, for the compound semiconductor power devices, a jig for testing electric characteristics of a device at room temperature is manufactured by each manufacturer. Further, for a reliability test to be performed at high temperature, since heat is produced from not only a heater but also the semiconductor device, the semiconductor device may be heated to a temperature of about 250-300° C. Such a heating may affect durability of a testing apparatus. Further, since operation frequency of the reliability testing apparatus is high (e.g., several GHz to several tens of GHz), there is a difficulty in manufacturing the jig.

### SUMMARY

Example embodiments of the inventive concept provide a semiconductor device testing apparatus that is configured to be able to test reliability and electric characteristics of a power semiconductor device at high temperature.

According to example embodiments of the inventive concepts, a semiconductor device testing apparatus may include a first socket configured to load a package, on which a semiconductor device to be tested may be mounted, and a second socket coupled to the first socket. The first socket may include an upper part including a hole configured to accommodate the package and a terminal pad provided at both side edges of the hole to hold input and output terminals of the package, and a lower part including a heating room, in which a heater and a temperature sensing part may be provided, the heater being configured to heat the semiconductor device and the temperature sensing part being configured to measure temperature of the semiconductor device. The second socket may include a probe card with a pattern that may be configured to receive test signals from an external power source.

In example embodiments, the terminal pad may be formed of an insulating material exhibiting a heat-resistance property under temperature of about 200-250° C.

In example embodiments, the temperature sensing part may include a thermocouple.

In example embodiments, the probe card may include at least one contact pin configured to deliver the test signal to an input terminal of the package.

In example embodiments, the probe card may include FR-5 or ceramic board.

In example embodiments, the contact pin may include a tungsten pin or a pogo pin.

In example embodiments, the semiconductor device may include AlGaN or GaN HEMT device.

In example embodiments, at least one of the first and second sockets may be formed of aluminum.

According to example embodiments of the inventive concepts, a semiconductor device testing apparatus including a base socket and a cover socket. The base socket may include an upward-protruding convex portion, in which a hole for loading a semiconductor device may be formed, and a heating room provided below the hole to apply heat to the semiconductor device, and the cover socket may include a concave portion that may be coupled to the convex portion and may be provided with a probe card for applying test signals to the semiconductor device.

In example embodiments, the heating room may be disposed to be in contact with the hole.

In example embodiments, the apparatus may further include a thermocouple provided in the heating room to measure a temperature of the semiconductor device. A thermocouple may be disposed to be in contact with the hole.

In example embodiments, the base socket may further include a terminal pad provided at both side edges of the hole and input/output terminals of the semiconductor device may be provided on the terminal pad.

In example embodiments, the apparatus may further include at least one contact pin that may be connected to the probe card and may be configured to deliver the test signals to the input/output terminals of the semiconductor device. The at least one contact pin may be disposed toward the convex portion.

In example embodiments, the contact pin may include a tungsten pin or a pogo pin.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 shows a semiconductor device testing apparatus according to example embodiments of the inventive concept.

FIG. 2 is a plan view illustrating a base socket of FIG. 1.

FIG. 3 is a sectional view of the base socket of FIG. 2.

FIG. 4 is a plan view illustrating a package including the base socket of FIG. 2 and a semiconductor device mounted thereon.

FIG. 5 shows the package of FIG. 4.

FIG. 6 is a plan view illustrating a cover socket of FIG. 1.

FIG. 7 is a sectional view illustrating the cover socket of FIG. 6.

FIGS. 8 and 9 are enlarged views of a probe board portion of FIG. 7.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concept relate to an apparatus for testing a semiconductor device, and in particular, to an apparatus configured to test electric characteristics and reliability of a semiconductor device. Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

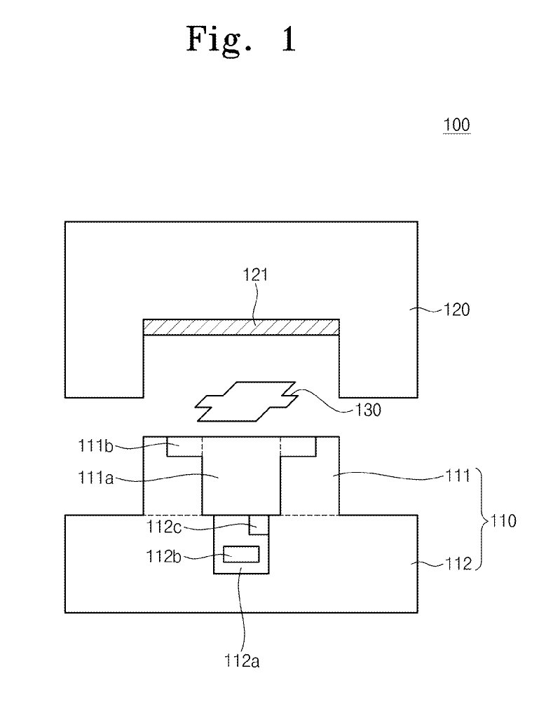

FIG. 1 shows a semiconductor device testing apparatus according to example embodiments of the inventive concept.

Referring to FIG. 1, according to example embodiments of the inventive concept, a semiconductor device testing apparatus 100 may include a base socket 110 and a cover socket 120. In example embodiments, the base socket 110 and the cover socket 120 may be formed of, for example, aluminum (Al).

A package 130 to be tested may be loaded on the base socket 110. A semiconductor device may be mounted in the package 130, when it is tested by the semiconductor device testing apparatus 100. The semiconductor device may be a compound semiconductor power device. For example, the semiconductor device may be an AlGaN or GaN HEMT device.

The base socket 110 may include an upper part 111 and a lower part 112.

The upper part 111 may be provided to have a hole 111a for accommodating or loading the package 130. During the testing process, the package 130 may be inserted into the hole 111a. At least one terminal pad 111b may be provided at both side edges of the hole 111a to support or hold input and output terminals of the package 130.

A heating room 112a may be provided in the lower part 112 to accommodate a heat source 112b that is configured to apply heat to the package 130. For example, the heating room 112a may be formed to be in contact with the hole 111a. As a temperature of the heat source 112b in the heating room 112a increases, an amount of heat to be delivered to the package 130 through the hole 111a may be increased, and thus, a temperature of the semiconductor device mounted in the package 130 may be increased. Such a heating may lead to a reduction in lifetime or reliability of the semiconductor device. In other words, a malfunction time may be shortened. Lifetime or reliability of the semiconductor device at room temperature may be calculated based on the shortened malfunction time. A temperature sensing part 112c may be disposed in the heating room 112a to measure a temperature of the semiconductor device mounted in the package 130. The temperature sensing part 112c may be configured to measure temperature of the semiconductor device and output the measured temperature to the outside.

The cover socket 120 may be coupled to the base socket 110. The cover socket 120 may include a probe card 121 with a pattern, to which test signals from an external power source are transmitted. The test signals may be provided in a form of, for example, voltage or current. The electric characteristics of the package 130 may also be measured or transmitted in a form of, for example, voltage and/or current. The test signals from the external power source may be transmitted to the input terminal of the package 130 through the probe card 121. Input and output terminals of the package 130 may be electrically connected to the semiconductor device provided in the package 130. Voltage and/or current output signals of the semiconductor device may be transmitted to the probe card 121 through the output terminal of the package 130. Meantime, as the semiconductor device is operated based on the test signal, heat may be generated from the package 130.

In example embodiments, a heat-radiating plate (not shown) may be provided on the cover socket 120. The heat-radiating plate may exclude heat generated in the base socket 110. For example, the heat-radiating plate may be realized using at least one of an aluminum heat-radiating plate, a copper heat-radiating plate, or an iron heat-radiating plate.

The base socket 110 and the cover socket 120 may be provided spaced apart from each other. The base socket 110 and the cover socket 120 may be coupled to each other to perform a process of testing the semiconductor device.

As described above, according to example embodiments of the inventive concept, the semiconductor device testing apparatus 100 may include the base socket 110 and the cover socket 120 that are provided spaced apart from each other. The base socket 110 may increase a temperature of the semiconductor device using the heat source 112b of the heating room 112a. Accordingly, it is possible to test electric characteristics and reliability of a semiconductor device at high temperature. Further, in the semiconductor device testing apparatus 100, the heat source 112b and the probe card 121 are separately provided in the base socket 110 and the cover socket 120, and thus, it is possible to prevent the probe card 121 from being thermally damaged. As a result, the process of testing a semiconductor device can be performed with improved reliability.

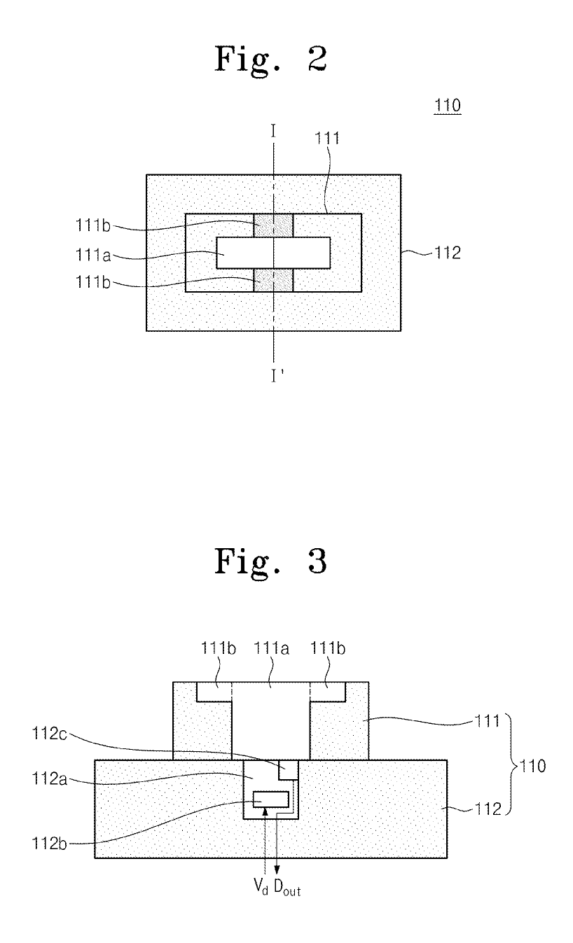

Hereinafter, the base socket 110 and the cover socket 120 will be described in more detail with reference to FIGS. 2 through 9.

FIG. 2 is a plan view illustrating a base socket of FIG. 1.

Referring to FIG. 2, the base socket 110 may include the upper part 111 and the lower part 112.

The upper part 111 may be provided at a central portion of the lower part 112, but example embodiments of the inventive concept may not be limited thereto. The hole 111a may be provided in the upper part 111 to accommodate or load the package 130. The hole 111a may be formed by etching the upper part 111 toward the lower part 112. Major and minor axes of the hole 111a may be designed in such a way that the package 130 can be loaded therein. The major axis may be perpendicular to a direction of I-I′, and the minor axis may be parallel to the direction of I-I′.

The terminal pad 111b may be formed at both side edges of the hole 111a to hold or support the input and output terminals of the package 130. The terminal pad 111b may be formed, for example, parallel to the direction of I-I′.

FIG. 3 is a sectional view of the base socket of FIG. 2.

FIG. 3 shows a sectional view of the base socket 110 taken along the direction I-I′ of FIG. 2. For concise description, overlapping description of elements previously described with reference to FIG. 2 may be omitted.

The base socket 110 may be formed to include the central portion having an upward protruding profile. For example, the base socket 110 may include the upper part 111 and the lower part 112.

The hole 111a may be formed through the upper part 111. For example, the hole 111a may extend to an interface between the upper part 111 and the lower part 112. However, example embodiments of the inventive concepts may not be limited thereto, and for example, the hole 111a may be formed to have enough depth to accommodate the package 130. The terminal pad 111b provided at both side edges of the hole 111a may be formed parallel to the etching direction of the hole 111a. The terminal pad 111b may be formed of an insulating material. Further, the terminal pad 111b may be formed of a material capable of providing a heat-resistance property under temperature of about 200-250° C.

The heating room 112a may be formed in the lower part 112 to accommodate the heat source 112b for heating the package 130. For example, the heating room 112a may be formed to be in contact with a lower part of the hole 111a. Accordingly, the heating room 112a can heat a bottom of the semiconductor device, and this makes it possible to improve heating efficiency.

The heat source 112b and the temperature sensing part 112c may be provided in the heating room 112a.

The heat source 112b may be, for example, a heater. The heat source 112b may be operated using an operation voltage Vd that is supplied from the outside. A temperature of the heat source 112b may be controlled by a signal to be transmitted from the outside through a wireless or wired way. The higher the temperature of the heat source 112b, the greater the amount of heat to be delivered to the package 130 through the hole 111a. In other words, the semiconductor device mounted in the package 130 can be heated using the heat source 112b.

The temperature sensing part 112c may be configured to measure the temperature of the semiconductor device and output the measurement temperature Dout to the outside. For example, the temperature sensing part 112c may include a thermocouple. The temperature sensing part 112c may be provided to be in contact with the lower part of the hole 111a.

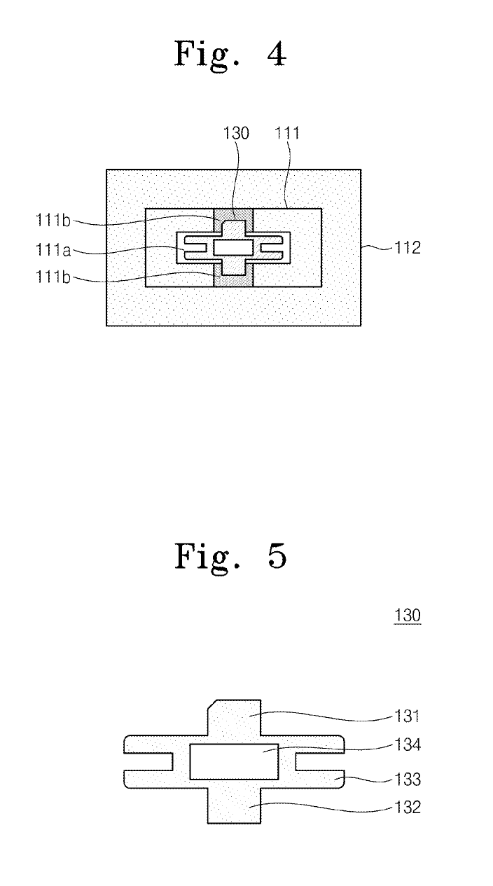

FIG. 4 is a plan view illustrating a package including the base socket of FIG. 2 and a semiconductor device mounted thereon. FIG. 5 shows the package of FIG. 4.

Referring to FIGS. 4 and 5, during the testing process, the package 130 may be inserted into the hole 111a.

The package 130 may include an input terminal 131, an output terminal 132, a ground terminal 133, and a package cover 134. The input terminal 131 may be used to deliver test signals from the outside to the package 130. The output terminal 132 may be used to deliver voltage and/or current output signals from the semiconductor device in the package 130 to the outside. The ground terminal 133 may be connected to a ground potential. The input terminal 131 and the output terminal 132 of the package 130 may be disposed on the terminal pad 111b.

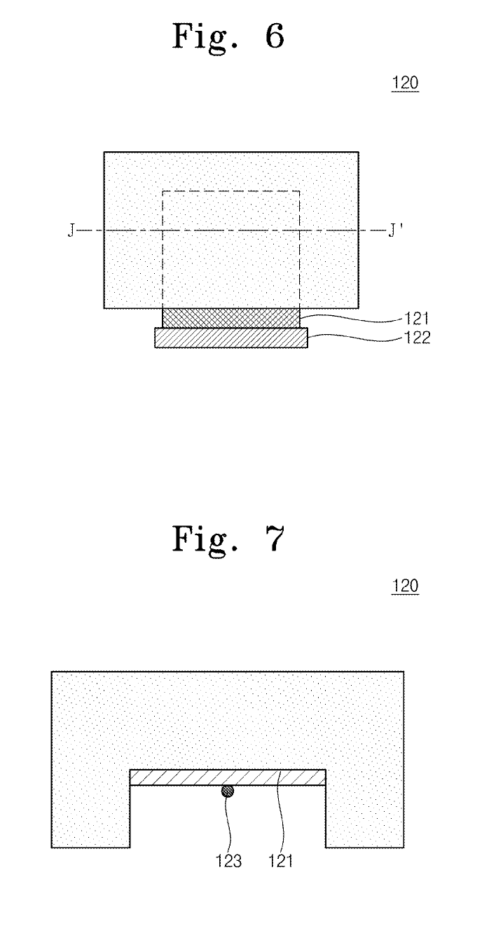

FIG. 6 is a plan view illustrating a cover socket of FIG. 1.

Referring to FIG. 6, the cover socket 120 may include the probe card 121 and a connector 122.

The probe card 121 and the connector 122 may protrude from a body of the cover socket 120 to be perpendicular to a direction of J-J′. The probe card 121 may include at least one pattern, to which test signals from an external power source may be transmitted. The test signals may be delivered to the input terminal of the package 130 through a contact pin (not shown), which will be described below. In example embodiments, the probe card 121 may be a vertical-type probe card or a micro-electro-mechanical systems (MEMS) probe card. The probe card 121 may include a FR-5 or ceramics board exhibiting a good heat-resistant property.

The connector 122 may be connected to the external power source to receive the test signal from the external power source. The test signal may be transmitted to the probe card 121 through the connector 122.

FIG. 7 is a sectional view illustrating the cover socket of FIG. 6.

FIG. 7 shows a sectional view of the cover socket 120 taken along the direction J-J′ of FIG. 6. For concise description, overlapping description of elements previously described with reference to FIG. 6 may be omitted.

The cover socket 120 may be formed to include a concave central portion. Accordingly, the cover socket 120 may be fittingly engaged with the base socket 110 of FIG. 3.

The cover socket 120 may include the probe card 121. The probe card 121 may include at least one contact pin 123.

The probe card 121 may be provided in the concave portion of the cover socket 120. As described above, the probe card 121 may be configured to receive the test signal from the external power source through the connector (not shown).

The contact pin 123 may be connected to the probe card 121. There is no need to limit the number of the contact pin 123. For example, if necessary, a plurality of the contact pins 123 may be provided on the probe card 121. The contact pin 123 may be configured to transmit the test signal to the input terminal of the package 130. For example, in the case where the base socket 110 and the cover socket 120 are engaged with each other, the contact pin 123 may be coupled to at least one of the input and output terminals of the package 130.

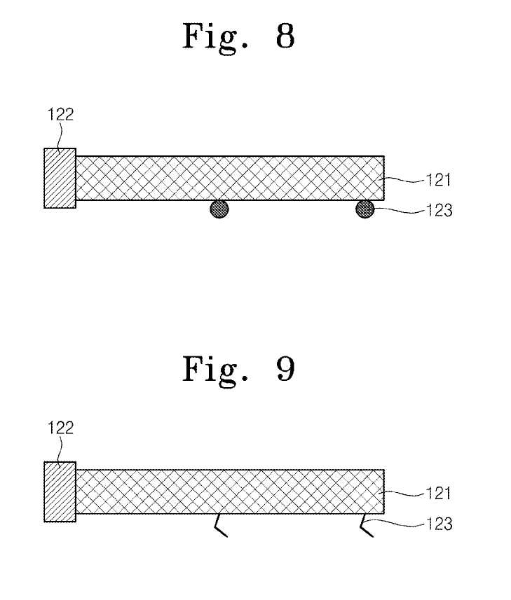

FIGS. 8 and 9 are enlarged views of a probe board portion of FIG. 7.

Referring to FIGS. 8 and 9, the probe card 121 may include, for example, two contact pins 123. However, example embodiments of the inventive concepts may not be limited to a specific number of the contact pins 123. For example, the number of the contact pins 123 may be changed depending on the number of terminals of the package 130.

Each of the contact pins 123 may be coupled to a corresponding one of the input and output terminals of the package 130. The contact pin 123 may be provided at a position corresponding to the position of the terminal pad 111b of the base socket 110. The contact pin 123 may be provided in a form of, for example, a tungsten pin or a pogo pin. The tungsten pin may include an elastic part made of tungsten, and the pogo pin may include a spring provided therein. The use of the tungsten or pogo pin makes it possible to improve contact property between the input and output terminals of the package 130 and the contact pin 123.

As described above, according to example embodiments of the inventive concept, the semiconductor device testing apparatus is configured in such a way that a heater and a probe board are disposed on a base socket a cover socket, respectively and separately, and thus, it is possible to prevent the probe board from being thermally damaged. In addition, the semiconductor device testing apparatus is configured to heat a bottom of a semiconductor device, and thus, testing process can be performed with improved heat efficiency.

Further, the semiconductor device testing apparatus can be used to test electric characteristics of the semiconductor device not only at room temperature but also at high temperature. Accordingly, a lifetime test and a burn-in test can be performed using the semiconductor device testing apparatus. In addition, a copper molybdenum copper (CMC) package, a ceramic/metal flange package, or a butterfly package for RF devices can be tested using the semiconductor device testing apparatus.

According to example embodiments of the inventive concept, the semiconductor device testing apparatus can test electric characteristics and reliability of a semiconductor device at a high temperature.

Further, the semiconductor device testing apparatus is configured in such a way that a heater and a probe board are disposed on a base socket a cover socket, respectively and separately, and thus, it is possible to prevent the probe board from being thermally damaged.

In addition, the semiconductor device testing apparatus is configured to heat a bottom of a semiconductor device, and thus, testing process can be performed with improved heat efficiency.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device testing apparatus, comprising:
a first socket configured to load a package, on which a semiconductor device to be tested is mounted; and
a second socket coupled to the first socket,
wherein the first socket comprises:
an upper part including a hole configured to accommodate the package and a terminal pad provided at both side edges of the hole to hold input and output terminals of the package; and
a lower part including a heating room, in which a heater and a temperature sensing part are provided, the heater being configured to heat the semiconductor device and the temperature sensing part being configured to measure temperature of the semiconductor device,
wherein the second socket comprises a probe card with a pattern that is configured to receive test signals from an external power source.

2. The semiconductor device testing apparatus of claim 1, wherein the terminal pad is formed of an insulating material exhibiting a heat-resistance property under temperature of about 200-250° C.

3. The semiconductor device testing apparatus of claim 1, wherein the temperature sensing part comprises a thermocouple.

4. The semiconductor device testing apparatus of claim 1, wherein the probe card comprises at least one contact pin configured to deliver the test signal to an input terminal of the package.

5. The semiconductor device testing apparatus of claim 4, wherein the probe card comprises FR-5 or ceramic board.

6. The semiconductor device testing apparatus of claim 4, wherein the contact pin comprises a tungsten pin or a pogo pin.

7. The semiconductor device testing apparatus of claim 1, wherein the semiconductor device comprises AlGaN or GaN HEMT device.

8. The semiconductor device testing apparatus of claim 1, wherein at least one of the first and second sockets is formed of aluminum.

9. A semiconductor device testing apparatus comprising a base socket and a cover socket, wherein the base socket comprises an upward-protruding convex portion, in which a hole for loading a semiconductor device is formed, and a heating room provided below the hole to apply heat to the semiconductor device, and
the cover socket comprises a concave portion that is coupled to the convex portion and is provided with a probe card for applying test signals to the semiconductor device.

10. The semiconductor device testing apparatus of claim 9, wherein the heating room is disposed to be in contact with the hole.

11. The semiconductor device testing apparatus of claim 9, further comprising a thermocouple provided in the heating room to measure a temperature of the semiconductor device, wherein thermocouple is disposed to be in contact with the hole.

12. The semiconductor device testing apparatus of claim 9, wherein the base socket further comprises a terminal pad provided at both side edges of the hole and input/output terminals of the semiconductor device are provided on the terminal pad.

13. The semiconductor device testing apparatus of claim 12, further comprising at least one contact pin that is connected to the probe card and is configured to deliver the test signals to the input/output terminals of the semiconductor device, wherein the at least one contact pin is disposed toward the convex portion.

14. The semiconductor device testing apparatus of claim 13, wherein the contact pin comprises a tungsten pin or a pogo pin.
